(19) United States
(12) Patent Application Publication
(10) Pub. No.: US 2012/0092032 A1
(43) Pub. Date: Apr. 19, 2012

(54) DEVICE FOR CHARACTERISING ELECTRIC OR ELECTRONIC COMPONENTS

(76) Inventors: Jean-Philippe Bourgoin, Voisins le Bretonneux (FR); Vincent Derycke, Montigny le Bretonneux (FR); Laurianne Nougaret, Cendras (FR); Gilles Dambrine, Wingles (FR); Henri Happy, Mouvaux (FR)

(21) Appl. No.: 13/142,007

(22) PCT Filed: Dec. 22, 2009
(86) PCT No.: PCT/FR09/01472

§ 371 Date: Dec. 13, 2011

(30) Foreign Application Priority Data
Dec. 24, 2008 (FR) 0807450

(51) Int. Cl. G01R 27/08

(52) U.S. Cl. 324/706

(57) ABSTRACT

The invention relates to an integrated device (PM) for characterising electric or electronic components (DUT), in particular nanometric ones, comprising a substantially insulating substrate (S) on which are provided four conducting pads (P₁, P₂, P₃, P₄), at least three resistive pads (R₁, R₃, R₄) connecting said pads together, and a transmission line (CPW) including a signal conductor (Cc) and at least one ground conductor (C_{L1}, C_{L2}), wherein: said resistive pads are arranged so as to connect a first conducting pad to a second and a fourth conducting pad, and to connect said fourth conducting pad to a third conducting pad; the signal conductor of the transmission line is connected to the first conducting pad; and the ground conductor of the transmission line is connected to the third pad.

The invention relates to a device and a method of characterizing electrical or electronic components, and more particularly components of nanometric dimensions, such as nanotubes, nanowires, etc.

Satisfactory characterization of such devices requires vector measurements to be taken of their impedances or of their S parameters as a function of frequency. In principle, these measurements may be performed by using commercially available vector network analyzers. Nevertheless, nanoelectronic components present impedances that are high, of kilohm order or more, whereas network analyzers are generally designed to characterize devices at 50 ohms (Ω).

The dimensions of these components also contribute to making them difficult to characterize.

For these reasons, it has only very recently become possible to perform vector characterization of nanoelectronic components such as a single-walled carbon nanotube: see the article by J. J. Plombon, Kevin P. O'Brien, Florian Gstrein, Valery M. Dubin, and Yang Jiao “High-frequency electrical properties of individual and bundled carbon nanotubes”, Applied Physics Letters 90, 063106 (2007). Previously, only scalar measurements had been made.

The invention seeks to make characterizing electrical and/or electronic components, and in particular nanometric components, simpler and more accurate.

In accordance with the invention, this object is achieved by means of an integrated device for characterizing nanometric electrical or electronic components, the device comprising a substantially insulating substrate on which there are deposited four conductive pads, at least three resistive tracks interconnecting said pads, and a transmission line having a signal conductor and at least one ground conductor, wherein:

said resistive tracks are arranged to connect a first conductive pad firstly to a second pad and secondly in parallel to a fourth pad, and to connect said fourth pad to a third pad;

the signal conductor of the transmission line is connected to said first conductive pad; and

the ground conductor of the transmission line is connected to said third pad.

Preferably, the transmission line may be a coplanar waveguide having a central signal conductor and two lateral conductors, said lateral conductors being connected together to form a ground ring that surrounds the tabs and the resistive tracks and that comes into electrical contact with said third pad.

Advantageously, said conductor pads may be arranged to form a quadrilateral, preferably a square or a lozenge, the first and fourth pads forming non-adjacent corners thereof.

The three resistive tracks may present the same resistance. Regardless of whether the resistances of these three tracks are mutually equal or different, they may be greater than or equal to 1 kΩ.

In a variant of the invention, the second and fourth pads may also be connected via respective integrated resistors to fifth and sixth pads. Advantageously, the resistances of said integrated resistors may be at least three times the highest resistance of said resistive tracks.

An electronic or electrical component to be characterized may be connected between said second and third pads. Preferably the electronic or electrical component to be characterized may be integrated in said substrate. In a variant, the device of the invention may include conductive contact tracks extending from each of said second and third pads and serving to form a measurement line to which an electrical or electronic component for characterizing can be connected. Optionally, an insulated conductive track may extend in a region situated between said electrical contact tracks, where it is possible to position said electrical or electronic component to be characterized; this insulated track may serve as a grid electrode for characterizing field effect transistors based on carbon nanotubes. In any event, the device of the invention and the component for characterizing form a Wheatstone bridge, also known as a “directional bridge” when used in this type of application. Advantageously, the resistances of the resistive tracks may be selected as a function of the estimated characteristics of the component for characterizing in order to ensure that the bridge is at least approximately balanced.

In other variant embodiment of the device of the invention:

said second and third pads need not be electrically connected to each other (open-circuit bridge);

said second and third pads may, on the contrary, be short-circuited in particular via a section of the or one of the ground conductors of the transmission line (short-circuited bridge);

said second and third pads may also be connected together by a resistive track, the assembly constituted by the four pads and the interconnected resistive tracks forming a balanced Wheatstone bridge.

These devices do not serve directly to characterize a component, but rather to calibrate the system used in order to take the measurement. To ensure that calibration takes place under the best conditions, it is most advantageous for the measurement bridge and for the three calibration bridges (open circuit, short-circuit, and balanced) all to be made on a common substrate.

Thus, the invention also provides an integrated device for characterizing nanometric electrical or electronic components, the device comprising at least a measurement bridge, a short circuit bridge, and a balanced bridge as described above, which bridges are all integrated on a common substrate and that are identical except for the connection, if any, between the second and third pads.

The measurement bridge without the component for characterizing (assumed to be a separate component that is fitted rather than being integrated on the substrate) may be used as an open-circuit calibration bridge. Nevertheless, it is preferable to provide a device having four bridges, including an integrated open-circuit bridge that is likewise identical to the other three individual devices except for the connection between the second and third pads.

The invention also provides:

the use of a device as described above for vector characterization of a nanometric electrical or electronic component connected between the second and third pads, by means of a vector network analyzer including an excitation probe connected to the transmission line of the device and a measurement probe connected in alternation to the second pad and to the fourth pad;

the use of a measurement bridge as described above in its variant having fifth and sixth conductive pads, for vector characterization of a nanometric electrical or electronic component connected between the second and third pads, by means of a vector network analyzer including an excitation probe connected to the transmission line of the device and a multi-point measurement probe connected to the fifth and sixth pads, and also to the ground conductor(s) of the transmission;

the use of an open-circuit, short-circuit, and/or balanced bridge as described above for calibrating a vector network analyzer during vector characterization of an electrical or electronic component, in particular a nanometric component, by means of a measurement bridge of the invention;

the use of a “composite” device having three or four individual bridges equally for calibrating a vector network analyzer and for vector characterization of an electrical or electronic component, in particular a nanometric component.

Other characteristics, details, and advantages of the invention appear on reading the following description made with reference to the accompanying figures given by way of example and in which, respectively:

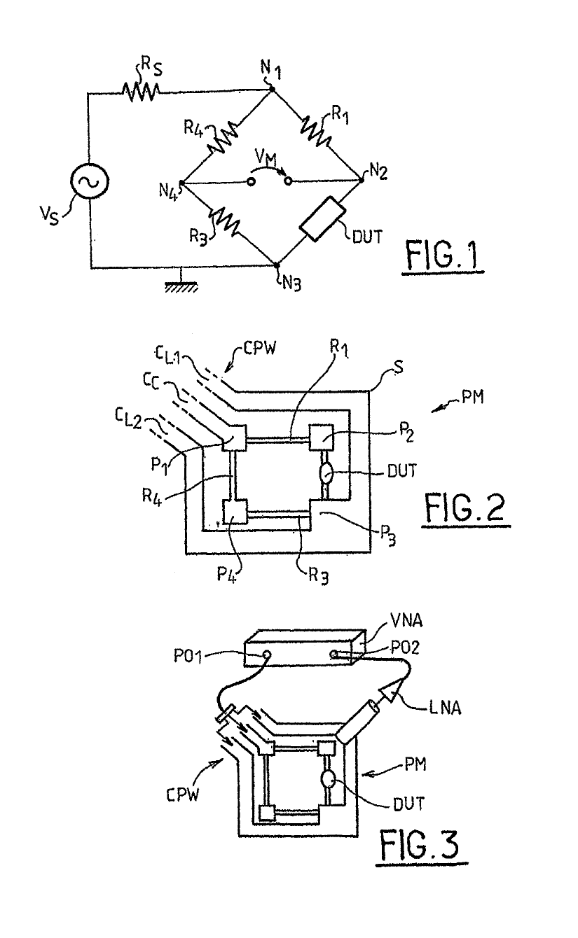

FIG. 1 shows the use of a vector network analyzer and a directional bridge for characterizing an electronic component;

FIG. 2 shows a measurement bridge in a first embodiment of the invention;

FIG. 3 shows the use of such a measurement bridge for characterizing a nanometric electronic component;

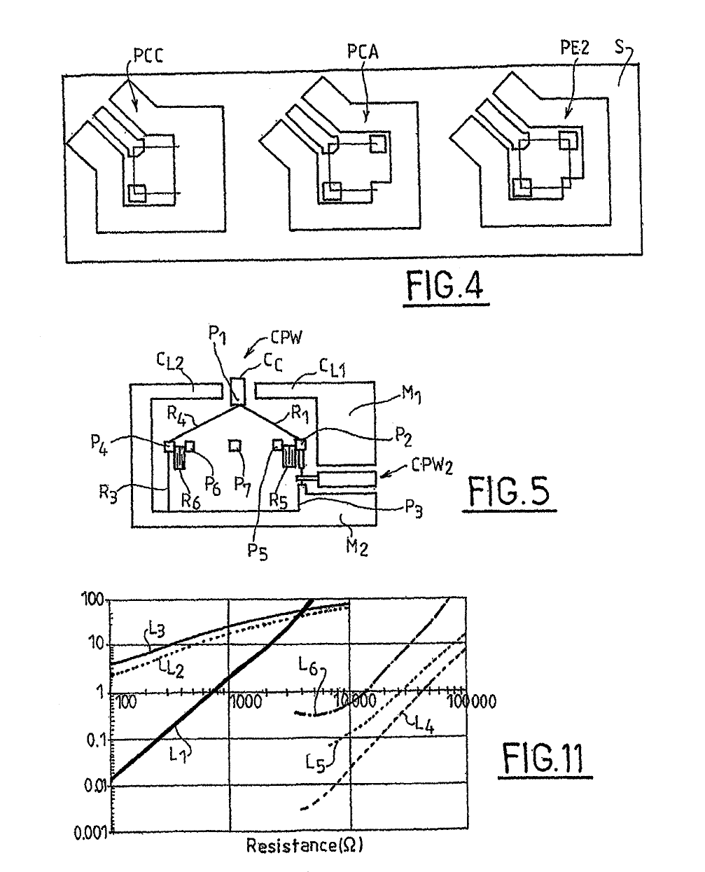

FIG. 4 shows three calibration bridges in the first embodiment of the invention;

FIG. 5 shows a measurement bridge in a second embodiment of the invention;

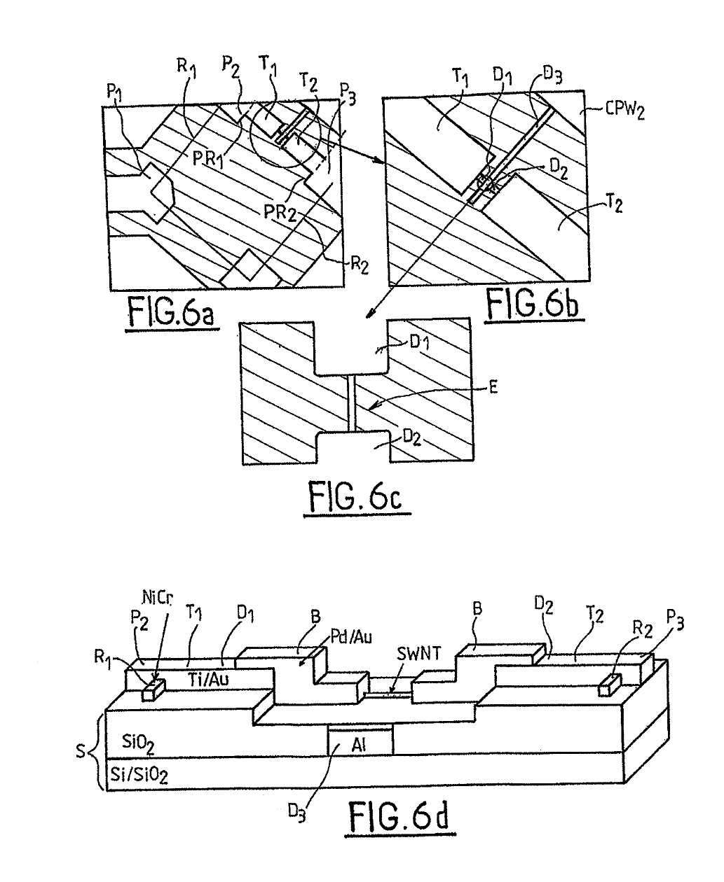

FIGS. 6a, 6b, 6c, and 6d are detail views of a measurement bridge in a third embodiment of the invention;

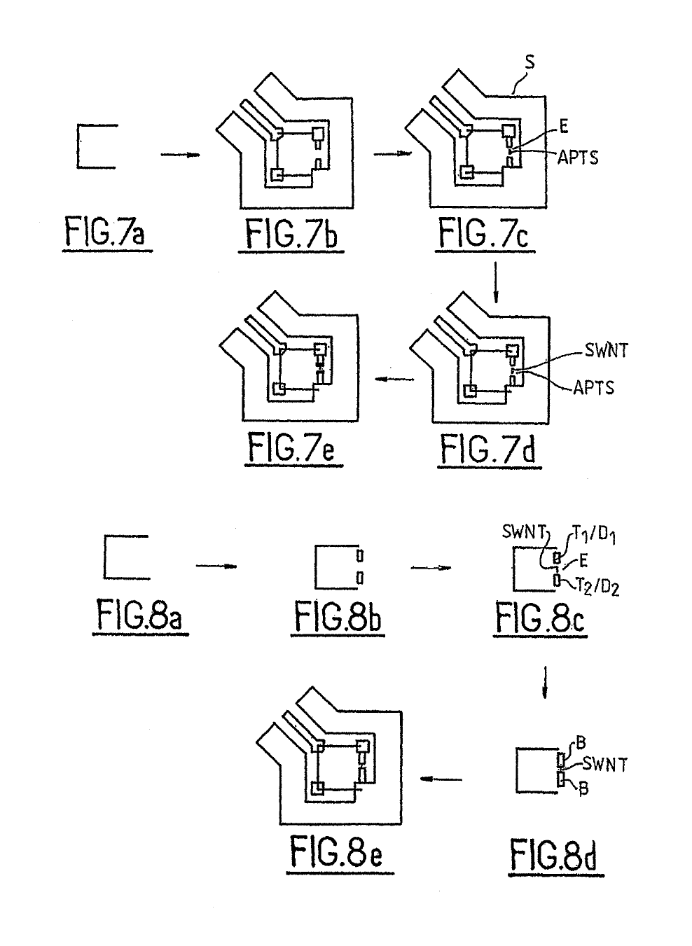

FIGS. 7a, 7b, 7c, 7d, and 7e show a first method of fabricating a measurement bridge including a carbon nanotube that is to be characterized;

FIGS. 8a, 8b, 8c, 8d, and 8e show a second method of fabricating a measurement bridge including a carbon nanotube that is to be characterized;

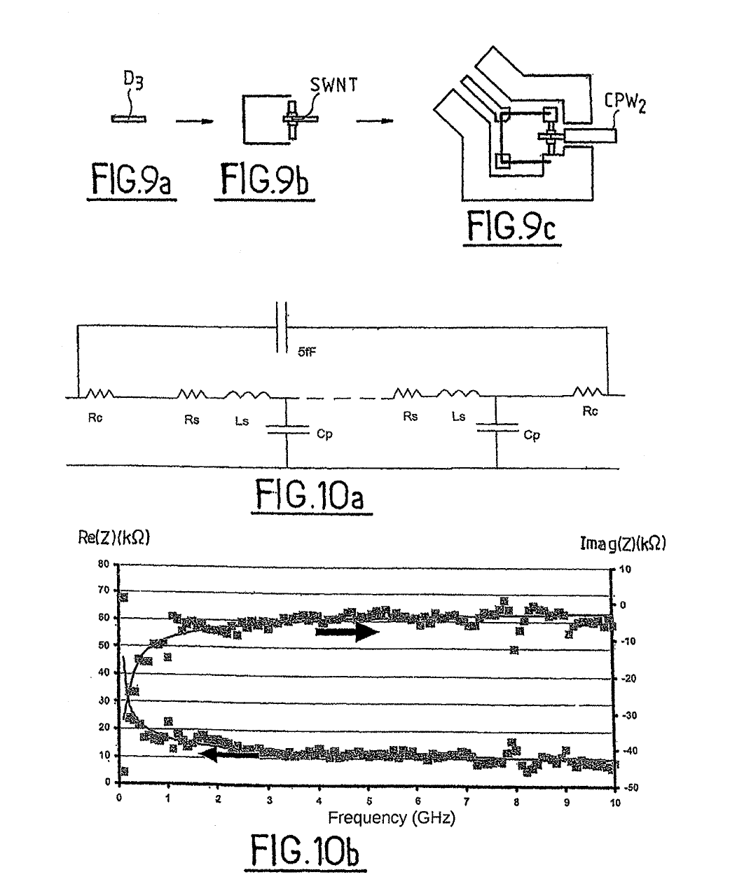

FIGS. 9a, 9b, and 9c show a third method of fabricating a measurement bridge including a carbon nanotube that is to be characterized;

FIG. 10a shows an electrical model of a carbon nanotube and the results of measuring such a nanotube;

FIG. 10b is a graph for use in comparing the results of a series of measurements performed on a carbon nanotube and theoretical results corresponding to the models of FIG. 10a; and

FIG. 11 is a graph illustrating the technical effect of the invention.

FIG. 1 shows a “Wheatstone bridge” or a “directional bridge” constituted by four nodes numbered N₁ to N₄ that are connected together by three resistors R₁ (connected between the nodes N₁ and N₂), R₃ (connected between the nodes N₃ and N₄), and R₄ (connected between the nodes N₁ and N₄). An electrical or electronic component that is to be characterized, i.e. the device under test (DUT) is represented by a two-terminal circuit of unknown complex impedance Z_{DUT} and it is connected between the nodes N₂ and N₃. A sinusoidal voltage generator Vₛ having internal resistance Rₛ is connected to the node N₁ while the node N₃ is connected to ground. The component DUT is characterized by causing the generator Vₛ to sweep through frequencies and, for each frequency, by measuring the amplitude and the phase of the voltage V_{M} between the nodes N₂ and N₄.

Let Vₛ′ be the voltage between the nodes N₁ and N₃. It is considered that the voltages V_{M} and Vₛ′ are measurable.

In the ideal case, when R₁=R₂=R₃=R_{bridge}, it is possible to consider three special cases for Z_{DUT}:

For Z_{DUT}=R_{bridge}, the voltage between the nodes N₄ and N₃, written V₄₃ is equal to the voltage between the nodes N₂ and N₃, written V₂₃. The voltage V_{M} which is the difference between these two voltages is thus zero.

$$\frac{{V}_{M}}{{V}_{S}^{′}} = \frac{{V}_{23} - {V}_{43}}{{V}_{S}^{′}} = \frac{\frac{{V}_{s}^{′}}{2} - \frac{{V}_{s}^{′}}{2}}{{V}_{S}^{′}} = 0$$

For Z_{DUT}=0 (perfect short circuit):

$$\frac{{V}_{M}}{{V}_{S}^{′}} = - \frac{{V}_{43 }}{{V}_{S}^{′}} = - \frac{\frac{{V}_{S}^{′}}{2}}{{V}_{S}^{′}} = - \frac{1}{2}$$

For 1/Z_{DUT}=0 (perfect open circuit):

$$\frac{{V}_{M}}{{V}_{S}^{′}} = \frac{{V}_{S}^{′} - {V}_{43}}{{V}_{S}^{′}} = \frac{{V}_{S}^{′} - \frac{{V}_{S}^{′}}{2}}{{V}_{S}^{′}} = \frac{1}{2}$$

It can be seen that the measured magnitude V_{M}/V′ₛ with a short circuit or an open circuit possesses the same modulus with a change of sign, i.e. a phase shift of 180°.

It is known that an ideal Wheatstone bridge is equivalent to a likewise ideal directional coupler.

An ideal directional coupler is characterized by a coupling coefficient, written α. Let a₁ be the complex amplitude of a wave injected into the input of the forward channel of such a coupler, and M be the complex amplitude of the wave leaving its coupled branch. The reflection factor Γ_{L} (ratio of the reflected wave divided by the incident wave) of a two-terminal circuit placed on the forward channel of the directional coupler at the end opposite from the generator is given by:

M=αΓ_{L} a₁

If α is known, measurements of a₁ and of M enable Γ_{L} to be detected.

The following three particular types of two-terminal circuit may be considered:

For Γ_{L}=0 (circuit corresponding to a non-reflective load):

$$\frac{M}{{a}_{1}} = 0$$

For Γ_{L}=−1 (circuit corresponding to a perfect short circuit):

$$\frac{M}{{a}_{1}} = - α$$

For Γ_{L}=1 (circuit corresponding to a perfect open circuit):

$$\frac{M}{{a}_{1}} = α$$

It can thus be seen that the perfect Wheatstone bridge behaves like a perfect directional coupler with α=½.

A real directional coupler (or a real Wheatstone bridge) is characterized by three complex magnitudes:

directivity Dᵢ;

insertion losses R_{f};

mismatch Dₑₛ.

In a coupler, directivity characterizes the ability on the coupled channel to separate the waves coming in one direction (e.g. from the generator) and from those coming in the other direction (e.g. from the load). A coupler is thus placed on a line in the direction corresponding to the signal that is to be measured. For an ideal coupler having infinite directivity, only the wave coming from the selected direction is present on the coupled channel. In a real coupler, there remains a very small component of the signal traveling in the opposite direction.

Insertion losses correspond to the attenuation of the incident wave on passing through the forward channel of the coupler.

Mismatch characterizes the change of impedance seen by the signal on going from one medium to another. The greater this difference, i.e. the greater the mismatch, the greater the fraction of the signal that is reflected by the change of medium, i.e. in this example by the output from the forward channel of the coupler: there thus exists a relationship between mismatch and reflection factor.

The measured reflection factor

$${Γ}_{M} = \frac{M}{{a}_{1}}$$

may be expressed as a function of these three magnitudes by the following relationship:

$${Γ}_{M} = {D}_{i} + \frac{{R}_{f} {Γ}_{DUT}}{1 - {D}_{es} {Γ}_{DUT}}$$

where Γ_{DUT} is the reflection factor of the two-terminal circuit under test.

In order to obtain the magnitudes Dᵢ, R_{f}, and Dₑₛ that characterize the imperfections of the directional coupler or of the Wheatstone bridge, it suffices to perform calibration that consists in measuring three particular standards (non-reflective load, short circuit, and open circuit) for which the reflection factors Γ_{DUT} are known, and to solve a system of three equations in three unknowns.

Assuming that calibration has been performed, it is possible from the measurement of Γ_{M} to deduce the reflection factor Γ_{DUT} for any device under test. By way of example, from Γ_{DUT} it is possible to deduce the impedance Z_{DUT} of the device under test as follows:

$${Z}_{DUT} = {Z}_{0} \frac{{Γ}_{DUT} + 1}{{Γ}_{DUT} - 1}$$

where Z₀ represents the reference impedance (fixed by the value of the “non-reflective load” standard used for calibration).

For high-frequency characterization of a “macroscopic” component, i.e. a component of millimeter dimensions, or at least of dimensions that are greater than several micrometers, it is possible to use a bridge constituted by discrete resistors with its node N₁ connected to a high frequency generator and its nodes N₂ and N₄ connected to a high frequency differential detector. As explained above, measurement is generally performed using an impedance of 50 Ω, which means that R₁=R₃=R₄=50 Ω. This consists in using a vector network analyzer of the kind including this type of bridge.

A general introduction to techniques for vector characterization of two-terminal circuits is provided by the application notes of the supplier Hewlett-Packard No. 1287-1 and 1287-2 that are accessible on the Internet at the URL http://www.hpmemory.org/an/pdf/an_{—}1287-1.pdf and http://www.hpmemory.org/an/pdf/an_{—}1287-2.pdf, respectively.

As explained above, these techniques cannot be transposed directly to characterizing “nanoelectronic” components such as nanotube transistors, because of their high impedance and their small dimensions, which make it difficult to achieve satisfactory contact with the probes of a commercial network analyzer.

The idea on which the invention is based consists in making a Wheatstone bridge that is integrated on a substantially insulating substrate of impedance and dimensions that are compatible with those of the component that is to be characterized. Such an integrated bridge serves, so to speak, as an interface between the microscopic component of high impedance and the macroscopic network analyzer designed for use at 50 Ω. Auxiliary bridges, preferably integrated on the same substrate as the measurement bridge, are used for calibrating the measurement bench.

An integrated measurement bridge PM is shown in FIG. 2. This device, having the dimensions 380 micrometers (μm)×380 μm is made on a substrate S of high-resistivity silicon “siltronix (100)” covered in a fine layer of oxide, having resistivity that is greater than 8000 ohm-centimeters (Ω·cm). It comprises:

four conductive pads P₁, P₂, P₃, and P₄ arranged in such a manner as to form a square;

a coplanar waveguide CPW constituted by a central conductor C_{C} connected to the first pad P₁ and two lateral conductors C_{L1}, C_{L2} that form a ring surrounding the four pads, and come into electrical contact with the pad P₃ opposite from the first pad P₁;

three resistive tracks R₁, R₃, and R₄ that are mutually identical, interconnecting the pads P₁ & P₂, P₃ & P₄, and P₄ & P₁, respectively; and

a device under test DUT connected between the pads P₂ and P₃.

The use of a coplanar waveguide having its lateral conductors surrounding the Wheatstone bridge is not essential, and any other transmission line (including at least a signal conductor and a ground conductor) could be used. Nevertheless, the embodiment described here presents best performance at high frequency.

The metal plating (pads and waveguides) is made of Ti/Au (a Ti layer having a thickness of 50 nanometers (nm) superposed on an Au layer having a thickness of 300 nm). The resistive tracks are made of NiCr, deposited by cathode sputtering and using an Ni/Cr 80/20 target, using radiofrequency (RF) power of 150 watts (W), thereby giving resistivity of 1 microhm-meter (μΩ·m).

All of the masking steps are performed by electron beam lithography. Making the resistive tracks during a single technological step serves to ensure very small dispersion between their resistances. Thus, even if it is possible for there to be fluctuations in the absolute values of the resistances, the ratios between the resistances are determined in a manner that is very accurate.

In general, at least the order of magnitude of the impedance of the two-terminal circuit that is to be characterized is known before making the measurement. Use is made of this knowledge to ensure that the measurement bridge including the two-terminal circuit is approximately balanced. Typically, this means that the resistive tracks R₁, R₃, and R₄ have an impedance of the order of 1 kilohm (kΩ) or more.

In order to characterize the two-terminal circuit DUT, i.e. in order to measure its complex impedance as a function of frequency, the FIG. 1 bridge needs to be connected to a high frequency signal generator, generally a synthesizer, and to a detector. The impedance of the generator theoretically has no impact on the operation of the bridge. Nevertheless, by using a 50Ω generator, the signals at the detector will be strongly attenuated because of the impedance of the bridge (about 1 kΩ). The detector system needs to present impedance that is much greater than that of the bridge, with the reactive portion (generally capacitive portion) of the impedance needing to be as small as possible. The stray capacitance of the detector in combination with the resistance of the bridge determines the passband of the system.

FIG. 3 shows the use of the measurement bridge PM of FIG. 1 in combination with a vector network analyzer VNA that incorporates an RF synthesizer and signal detector. A high frequency sinewave signal (at several megahertz (MHz) or gigahertz (GHz)) is generated by the analyzer VNA at the port PO1 and is injected into the bridge via a conventional coplanar high frequency probe having three ground-signal-ground contacts, with the signal central contact being connected to the central conductor C_{C} of the coplanar waveguide CPW and with the two ground contacts being connected to the two lateral contacts C_{L1} and C_{L2} of the waveguide. Detection is performed using a high frequency passive probe (e.g. a cascade microtech FPM ×100 probe) having a single signal contact, connected to the port PO2 of the analyzer VNA via a low noise amplifier LNA via a broadband low noise amplifier LNA possessing gain of 20 decibels (DB) (a linear factor of 100) that serves to compensate for the attenuation of the signal through the high impedance probe (5 kΩ/50Ω=100).

The measurement is performed in two stages, in which the high impedance probe is connected in alternation to the pads P₂ and P₄ of the bridge. The parameter measured by the analyzer VNA in each of these two positions is the transmission factor S₂₁ₚ₁ and S₂₁ₚ₂ (vector magnitudes). The reflection factor of the DUT is given by the difference:

D₂₁_{_{—}}_{DUT}=S₂₁ₚ₁_{_{—}}_{DUT}−S₂₁ₚ₂_{_{—}}_{DUT}.

As explained above, measurement proper needs to be preceded by a calibration step using three additional bridges PCA, PCC, and PEQ as shown in FIG. 4 in order to measure respectively the directivity, the transmission loss, and the mismatch. In the bridge PCA, the pads P₂ and P₃ are insulated from each other, in other words the two-terminal circuit DUT of the bridge PM is replaced by an open circuit. In the bridge PCC, on the contrary, the pads P₂ and P₃ are short circuited, the two-terminal circuit DUT being replaced by a length of the conductor C_{L1} of the waveguide CPW. In the bridge PEQ, the two-terminal circuit DUT is replaced by a resistive track R₂ that serves to balance the bridge; this is the simplest case, with:

R₁=R₂=R₃=R₄

Advantageously, all four bridges PM, PCA, PCC, and PEQ are made simultaneously on the same substrate in order to ensure that the measurement bridge and the calibration measurements are strictly identical to one another except concerning the connection (or lack of connection) between the pads P₂ and P₃. In a variant, three bridges may suffice, the open circuit bridge PCA being used for characterizing a component that is fitted thereto.

Calibration of the two-terminal circuit DUT thus requires eight individual measurements to be performed (two for each bridge), and a system of three linear equations to be solved (in order to determine directivity, transmission loss, and mismatch on the basis of the three calibration measurements).

High impedance probes are fragile and their passband is limited by the presence of stray capacitances.

To mitigate these problems, the integrated bridge of FIG. 5 includes two zigzag resistors R₅ and R₆ that are connected in series between the pads P₂, P₄ and two additional pads P₅, P₆ that can be used as contact pads for a high frequency measurement probe at 50Ω. For example, it is possible to use a five-contact probe of the ground-signal-ground-signal-ground type. The two signal contacts are connected to the pads P₅ and P₆, the outer ground contacts are connected to the lateral conductors of the coplanar waveguide CPW, and the central ground contact is connected to a ground pad P₇ situated between the signal pads P₅ and P₆. The pad P₇ may be connected to ground directly or solely via the probe.

Integrating resistors in the bridge makes it possible to reduce stray capacitances, and thus to increase passband, and makes it possible to use probes that present greater mechanical strength. In addition, the reproducibility of the measurements is bound to be improved.

The use of integrated resistors of linear structure, as opposed to of zigzag structure, makes it possible subsequently to reduce the stray capacitances. However, that requires a special step of deposition by sputtering of a high resistivity material such as NiCr, for example.

The resistances of the resistors R₅ and R₆ is greater than the resistances of the resistors R₁, R₂, and R₃ by a factor of at least three. Another advantage of using a multicontact probe is that the number of measurements that need to be taken is divided by two since the probe does not need to be connected in succession to two different measurements pads, as in the example of FIG. 3.

Naturally, the FIG. 5 high impedance measurement bridge is preferably provided with the corresponding calibration measurements (not shown).

It is of interest to observe that the shape of the FIG. 5 bridge differs from that of the FIG. 3 bridge: the measurement pads are not arranged in a quadrilateral, but rather they form an irregular pentagon; furthermore, the pads P₁ and P₃ are not genuinely distinct from the conductors C_{C} and C_{L1}/C_{L2} of the coplanar waveguide CPW. On the right of the figure, the conductor C_{L1} comes into contact with two rectangular metallizations M₁ and M₂ that in turn constitute the lateral conductors of a second coplanar waveguide CPW₂ of a measurement channel for fitted nano-components.

This measurement channel, which is particularly suitable for characterizing single-walled carbon nanotube transistors (SWNTs) is shown in greater detail in FIGS. 6a-6d.

In FIGS. 6a-6c, it can be seen that a first conductive contact track T₁ extends from the pad P₂ to the pad P₃ and conversely a second contact track T₂ extends from the pad P₃ to the pad P₂. The two contact tracks are extended by respective fingers D₁, D₂ of width that is of the order of a few hundreds of nanometers (800 nm in the example of the figure). A gap E, likewise of a few hundreds of nanometers (800 nm in the example of the figure), lies between the ends of the fingers.

As shown in FIG. 6d, a carbon nanotube SWNT may be positioned, e.g. using known dielectrophoresis techniques, in the gap E, and may be electrically connected to the fingers D₁ and D₂ by depositing a bilayer B of palladium/gold (30/80 nm).

These dielectrophoresis techniques are described in the article by A. Vijayaraghavan, S. Blatt, D. Weissenberger, M. Oron-Carl, F. Hennrich, D. Gerthsen, H. Hahn, and R. Krupke, Nano Lett. 2007, 7, (6), pp. 1556-1560.

A fine electrode D3 made of aluminum, insulated by a 2 nm thick oxide layer and connected to the second coplanar waveguide CPW₂ extends under the gap E in order to act as the grid electrode of the transistor formed by the nanotube SWNT connected to the electrodes D₁ and D₂ acting as drain and source contacts.

FIGS. 7a-7e, 8a-8e, and 9a-9c show in greater detail three methods of fabricating an integrated measurement bridge of the invention that includes a carbon nanotube that is to be characterized.

The first method (FIGS. 7a-7e) is based on modifying the substrate S by localized grafting of molecules so as to obtain preferential absorption of a nanotube (or any other nano-article) at a measurement location E. This method comprises:

FIG. 7a: fabricating resistors out of Ni/Cr in an electron lithography step comprising: depositing a layer of resin, marking a lithographic pattern in the resin by means of an electron beam, developing the resin, depositing an Ni/Cr alloy by cathode sputtering, and removing the remaining resin (lift-off);

FIG. 7b: fabricating the structure of the bridge by electron lithography;

FIG. 7c: preparing a “sticky” zone at the measurement location E by: depositing resin, marking the “sticky” zone by using an electron beam, developing the resin, grafting a molecular monolayer of amino-propyl-triethoxy-silane (APTS) in the gaseous phase, and then removing the resin;

FIG. 7d: depositing a drop of a solution of carbon nanotubes in N-methyl-pyrrolidone (NMP) on the wafer, or immersing the wafer in such a solution. The nanotubes “stick” only to the APTS-grafted zone, with the remainder of the solution being rinsed off; this stochastic process is repeated until a single correctly-positioned nanotube is obtained having the desired orientation in the measurement location; and

FIG. 7e: depositing electrical contacts made of Pd/Au on the nanotube by means of a new electron lithography step.

The second method (FIGS. 8a-8e) is based on a dielectrophoresis technique. This method comprises:

FIG. 8a: fabricating Ni/Cr resistors by an electron lithography step, as in the first method;

FIG. 8b: fabricating local Au electrodes T₁/D₁ and T₂/D₂ at the ends of the measurement location E in a new electron lithography step;

FIG. 8c: depositing a nanotube between these electrodes, this comprising: depositing a drop of nanotube solution on the substrate S at the location E, placing two points on the electrodes, applying an alternating electric field (typically 10 volts (V), 15 MHz, for a duration of 3 minutes (min)); rinsing;

FIG. 8d: depositing Pd/Au contacts B on the deposited nanotube SWNT using a new electron lithography step; and

FIG. 8e: fabricating the structure of the bridge by electron lithography.

The third method (FIGS. 9a-9c) is a variant of the second method and likewise includes fabricating an insulated grid to make the nanotube operate as a field effect transistor. This method begins by fabricating an aluminum grid D3 and oxidizing its surface so as to form the insulation of the grid (FIG. 9a). Thereafter, calibrated resistors of Ni/Cr and electrodes of Ti/Au are fabricated, and a carbon nanotube is deposited by dielectrophoresis over the grid (FIG. 9b, corresponding to FIGS. 8a-8d of the second method). Finally, the structure of the bridge is fabricated by electron lithography (FIG. 9c).

In the same manner, a grid electrode may be used in combination with the method of deposition by molecular grafting (first method).

These techniques described with reference to depositing carbon nanotubes may be adapted to depositing other nano-articles, such as carbon nanotubes that are doped, e.g. with boron or nitrogen; nanotubes of boron nitride, or indeed other types of nanotube; nanowires of semiconductor materials (silicon, GaAs, InP, . . . ), or of metal (gold, palladium, platinum, . . . ).

A bridge that includes a measurement channel for nano-articles, such as the bridge shown in FIGS. 5 and 6a-6d requires an additional calibration step for characterizing said measurement channel. Thus, after calibrating the bridge using three measurements in open circuit, short circuit, and on a matched load (see FIG. 4), it is necessary to perform a fourth measurement using a bridge identical to that used for characterizing the nano-article, but empty. This fourth measurement serves to obtain the electrical characteristics of the measurement channel, which may be modeled by a spray capacitance of a few femto-farads (1 fF=10⁻¹⁵ F), in parallel with the nano-article. This capacitance is extracted from the imaginary portion of the admittance, obtained by converting the reflection factor (parameter S) into a parameter Y.

After these calibration steps, the reflection factor of the nanotube is measured relative to the reference planes PR₁, PR₂ situated at the ends of the measurement channels. The parameter S as measured in this way is converted into a parameter Z in order to obtain the impedance of the nanotube.

As shown in FIG. 10a, the nanotube is modeled by a distributed network LₛLₛCₚ connected in series between two contact resistances R_{c}, with the R_{c}-RₛLₛCₚ-R_{c} circuit being connected in parallel with the stray capacitance of the measurement channel (specifically 5 fF).

The points of FIG. 10b show the impedance values as a function of frequency of the real portion and of the imaginary portion of a carbon nanotube connected to a measurement bridge of the invention. The continuous lines represent the corresponding theoretical values obtained from the model of FIG. 10a with optimized values for the parameters R_{c}, Rₛ, Lₛ, and Cₚ. These values, and the corresponding normalized values (per unit length) are given in the following table:

| Element | R_{c} | Rₛ | Cₚ | Lₛ |
|---|---|---|---|---|
| Extracted | ~9 | ~30 | ~30 | ~280 |
| value | kΩ | kΩ | fF | nH |
| Normalized | ~8.2 | ~37.5 | ~37.5 | ~350 |
| value | kΩ/μm | kΩ/μm | fF/μm | nH/μm |

FIG. 11 shows the technical effect obtained by the invention. This graph shows the uncertainty with which a resistance R lying in the range 100Ω to 100 kΩ is measured at a frequency lying in the range 300 kHz to 6 GHz while using a conventional 50Ω measurement probe (lines L₁: range 300 kHz-1.3 GHz; L₂: range 1.3 GHz-3 GHz; L₃: range 3 GHz-6 GHz) and a measurement bridge of the invention having a characteristic impedance of 3.5 kΩ (lines L₄: range 300 kHz-1.3 GHz; L₅: range 1.3 GHz-3 GHz; L₆: range 3 GHz-6 GHz). The measurements were performed using an Agilent 8753ES vector network analyzer fitted with a 7 mm APC metrology connector.

The figure shows that at impedance values that are typical for nanoelectronic components (1 kΩ-10 kΩ), the invention makes it possible to reduce measurement uncertainty by two to three orders of magnitude. This result is obtained by means of a device (measurement bridge) that is simple and that can be fabricated at low cost using conventional microelectronic techniques, and by using conventional measurement methods.

1. An integrated device (PM) for characterizing electrical or electronic components (DUT), in particular nanometric components, the device comprising a substantially insulating substrate (S) on which there are deposited four conductive pads (P₁, P₂, P₃, P₄), at least three resistive tracks (R₁, R₃, R₄) interconnecting said pads, and a transmission line (CPW) having a signal conductor (C_{c}) and at least one ground conductor (C_{L1}, C_{L2}), wherein:
said resistive tracks are arranged to connect a first conductive pad (P₁) firstly to a second pad (P₂) and secondly in parallel to a fourth pad (P₄), and to connect said fourth pad to a third pad (P₃);
the signal conductor of the transmission line is connected to said first conductive pad; and
the ground conductor of the transmission line is connected to said third pad.

2. A device according to claim 1, wherein the transmission line is a coplanar waveguide having a central signal conductor and two lateral conductors, said lateral conductors being connected together to form a ground ring that surrounds the tabs and the resistive tracks and that comes into electrical contact with said third pad.

3. A device according to claim 2, wherein said conductor pads are arranged to form a quadrilateral, the first and fourth pads forming non-adjacent corners thereof.

4. A device according to claim 3, wherein the quadrilateral is a square or a lozenge.

5. A device according to claim 1, wherein the three resistive tracks present the same resistance.

6. A device according to claim 1, wherein the three resistive tracks present resistances that are greater than or equal to 1 kΩ.

7. A device according to claim 1, wherein the second and fourth pads are also connected via respective integrated resistors (R₆, R₇) to fifth and sixth pads (P₅, P₆).

8. A device according to claim 7, wherein the resistances of said integrated resistors are at least three times the highest resistance of said resistive tracks.

9. A device according to claim 1, wherein an electronic or electrical component to be characterized (DUT) is connected between said second and third pads.

10. A device according to claim 9, wherein said electronic or electrical component to be characterized (DUT) is integrated in said substrate.

11. A device according to claim 1, including conductive contact tracks (T₁, D₁, D₂, T₂) extending from each of said second and third pads and serving to form a measurement line to which an electrical or electronic component for characterizing can be connected.

12. A device according to claim 11, also including an insulated conductive track (D₃) extending in a region (E) situated between said electrical contact tracks, where it is possible to position said electrical or electronic component to be characterized.

13. A device (PCA) according to claim 1, wherein said second and third pads are not electrically connected to each other.

14. A device (PCC) according to claim 1, wherein said second and third pads are short-circuited.

15. A device according claim 14, wherein said second and third pads are short-circuited by means of a section of the or one of the ground conductors of the transmission line.

16. A device (PEQ) according to claim 1, wherein said second and third pads are connected together by a resistive track, the assembly constituted by the four pads and the interconnected resistive tracks forming a balanced Wheatstone bridge.

17. An integrated device characterizing nanometric electrical or electronic components, the device having the following three individual devices integrated on a common substrate:
1) a first integrated device (PM) for characterizing electrical or electronic components (DUT), in particular nanometric components, the device comprising a substantially insulating substrate (S) on which there are deposited four conductive pads (P₁, P₂, P₃, P₄), at least three resistive tracks (R₁, R₃, R₄) interconnecting said pads, and a transmission line (CPW) having a signal conductor (C_{c}) and at least one ground conductor (C_{L1}, C_{L2}), wherein:
said resistive tracks are arranged to connect a first conductive pad (P₁) firstly to a second pad (P₂) and secondly in parallel to a fourth pad (P₄), and to connect said fourth pad to a third pad (P₃);
the signal conductor of the transmission line is connected to said first conductive pad; and
the ground conductor of the transmission line is connected to said third pad, wherein an electronic or electrical component to be characterized (DUT) is connected between said second and third pads;
2) a second integrated device (PM) for characterizing electrical or electronic components (DUT), in particular nanometric components, the device comprising a substantially insulating substrate (S) on which there are deposited four conductive pads (P₁, P₂, P₃, P₄), at least three resistive tracks (R₁, R₃, R₄) interconnecting said pads, and a transmission line (CPW) having a signal conductor (C_{c}) and at least one ground conductor (C_{L1}, C_{L2}), wherein:
said resistive tracks are arranged to connect a first conductive pad (P₁) firstly to a second pad (P₂) and secondly in parallel to a fourth pad (P₄), and to connect said fourth pad to a third pad (P₃);
the signal conductor of the transmission line is connected to said first conductive pad; and
the ground conductor of the transmission line is connected to said third pad, and wherein said second and third pads are short-circuited;
and
3) a third integrated device (PM) for characterizing electrical or electronic components (DUT), in particular nanometric components, the device comprising a substantially insulating substrate (S) on which there are deposited four conductive pads (P₁, P₂, P₃, P₄), at least three resistive tracks (R₁, R₃, R₄) interconnecting said pads, and a transmission line (CPW) having a signal conductor (C_{c}) and at least one ground conductor (C_{L1}, C_{L2}), wherein:
said resistive tracks are arranged to connect a first conductive pad (P₁) firstly to a second pad (P₂) and secondly in parallel to a fourth pad (P₄), and to connect said fourth pad to a third pad (P₃);
the signal conductor of the transmission line is connected to said first conductive pad; and
the ground conductor of the transmission line is connected to said third pad, and wherein said second and third pads are connected together by a resistive track, the assembly constituted by the four pads and the interconnected resistive tracks forming a balanced Wheatstone bridge,
and wherein these three individual devices being identical except for the connection, if any, between the second and third pads.

18. A device according to claim 17, also including a fourth individual device comprising a substantially insulating substrate (S) on which there are deposited four conductive pads (P₁, P₂, P₃, P₄), at least three resistive tracks (R₁, R₃, R₄) interconnecting said pads, and a transmission line (CPW) having a signal conductor (C_{c}) and at least one ground conductor (C_{L1}, C₁₂), wherein:
said resistive tracks are arranged to connect a first conductive pad (P₁) firstly to a second pad (P₂) and secondly in parallel to a fourth pad (P₄), and to connect said fourth pad to a third pad (P₃);
the signal conductor of the transmission line is connected to said first conductive pad; and
the ground conductor of the transmission line is connected to said third pad, wherein said second and third pads are not electrically connected to each other, said fourth device likewise being integrated on the same substrate and being identical to the other three individual devices except for the connection between the second and third pads.

19. The use of a device according to claim 1 for vector characterization of a nanometric electrical or electronic component connected between the second and third pads, by means of a vector network analyzer (VNA) including an excitation probe connected to the transmission line of the device and a measurement probe connected in alternation to the second pad and to the fourth pad.

20. The use of a device according to claim 7 for vector characterization of a nanometric electrical or electronic component connected between the second and third pads, by means of a vector network analyzer (VNA) including an excitation probe connected to the transmission line of the device and a multi-point measurement probe connected to the fifth and sixth pads, and also to the ground conductor(s) of the transmission line.

21. The use of a device according to claim 12 for:
1) calibrating a vector network analyzer (VNA) during vector characterization of a nanometric electrical or electronic component connected between the second and third pads, by means of a vector network analyzer (VNA) including an excitation probe connected to the transmission line of the device and a multi-point measurement probe connected to the fifth and sixth pads, and also to the ground conductor(s) of the transmission line.

22. The use of a device according to claim 17 for:
1) calibrating a vector network analyzer (VNA) during vector characterization of a nanometric electrical or electronic component connected between the second and third pads, by means of a vector network analyzer (VNA) including an excitation probe connected to the transmission line of the device and a multi-point measurement probe connected to the fifth and sixth pads, and also to the ground conductor(s) of the transmission line.
